(19) United States
(12) Patent Application Publication
(10) Pub. No.: US 2014/0273504 A1
(43) Pub. Date: Sep. 18, 2014

(54) SELECTIVE DEPOSITION BY LIGHT EXPOSURE

(71) Applicant: APPLIED MATERIALS, INC., Santa Clara, CA (US)

(72) Inventors: Aneesh Nainani, Palo Alto, CA (US); Joseph Johnson, Redwood City, CA (US); Er-Xuan Ping, Fremont, CA (US); Adam Brand, Palo Alto, CA (US); Mathew Abraham, Mountain View, CA (US)

(73) Assignee: APPLIED MATERIALS, INC., Santa Clara, CA (US)

(21) Appl. No.: 13/838,960

(22) Filed: Mar. 15, 2013

(51) Int. Cl. H01L 21/02; H01L 21/285

(52) U.S. Cl. CPC H01L 21/02277; H01L 21/28506
USPC 438/758; 118/722; 118/725

(57) ABSTRACT

A substrate processing chamber comprising a chamber wall enclosing a process zone having an exhaust port, a substrate support to support a substrate in the process zone, a gas distributor for providing a deposition gas to the process zone, a solid state light source capable of irradiating substantially the entire surface of the substrate with light, and a gas energizer for energizing the deposition gas.

### BACKGROUND

Embodiments of the present invention relate to the selective deposition of materials in semiconductor processing.

In the manufacture of electronic and photo-electronic devices, such as for example, transistors, integrated circuits, displays and solar panels, layers of dielectric, semiconducting, and electrically conducting materials are deposited on a substrate, patterned, and then etched to form active and passive features. Conformal processes such as atomic layer deposition (ALD) and chemical vapor deposition (CVD) are being increasingly used to form transistors having a three dimensional (3D) layout and features for making both logic and memory integrated circuits. Conformal deposition processes deposit a conformal film covering both the vertical and horizontal surfaces of the exposed features.

However, it is often desirable to selectively deposit material on the exposed horizontal surfaces of features but not on their vertical surfaces. For example, in high-k dielectric ALD processes which are used to form metal gates 1, as shown in FIGS. 1A and 2A, it is desirable to deposit a high-k dielectric 2 having a high permittivity (k) on the bottom surfaces 3 of vias 4 formed in a silicon wafer 5 but not on the vertical sidewall spacers 6. However, as shown, the high-k dielectric 2 forms conformal deposits on both the vertical sidewall spacers 6 and the horizontal bottom surface 3. The high-k dielectric 2 deposited on the sidewall spacers 6 increases the gate-to-plug capacitance and also reduces the volume available to subsequently fill the metal gate 1 with metal. As another example, the conformal nature of CVD metal deposition of contact plugs and metal gates causes the growth of deposited metal on the vertical sidewalls 7 of the contact plug feature 8, as shown in FIGS. 1B and 2B, which eventually merge and close off leaving a gap seam 9 within the feature 8. Such gaps seams 9 increase the resistivity and affect the strain levels of the feature 8. In yet another example, in selective CVD deposition of cobalt-magnesium (Co/Mg) 10 for back-end-of-line (BEOL) applications which is used to improve electromigration characteristics in the underlying copper, the cobalt-magnesium 10 tends to conformally deposit on all the exposed substrate surfaces 11, as shown in FIG. 1C, and not selectively on the exposed surface 12 of the copper feature 13, introducing additional process complexities.

Selective deposition processes such as epitaxial growth have been developed to selectively grow material provided in a gaseous state onto seed or nucleation layers formed on a substrate. For example, silicon and germanium are grown from silane and germane gases on seed layers of silicon or germanium, respectively. While selective deposition can be achieved using epitaxial processes, they require deposition of a seed layer prior to achieving selective deposition. Further, in certain processes such as metal gate and high-k dielectric deposition, as described above, a seed layer of a different material cannot be used as it would adversely affect the desired electrical properties of the feature or is simply difficult to deposit on underlying surfaces. The seed layer can also adversely affect the electrical properties due to overlay issues.

For reasons that include these and other deficiencies, and despite the development of various selective deposition processes, further improvements in selective deposition and related apparatus are continuously being sought.

### SUMMARY

A substrate processing chamber comprising a chamber wall enclosing a process zone having an exhaust port, a substrate support to support a substrate in the process zone, a gas distributor for providing a deposition gas to the process zone, a solid state light source capable of irradiating substantially the entire surface of the substrate with light, and a gas energizer for energizing the deposition gas.

A substrate fabrication process comprises placing a substrate in a process zone, the substrate comprising first exposed surfaces comprising at least one first material having a first bandgap energy level, irradiating the substrate with light having a wavelength selected in relation to the first bandgap energy level of the first material, and depositing material on the first exposed surfaces by providing an energized deposition gas in the process zone.

A substrate processing method comprises placing a substrate in a process zone, the substrate comprising an array of first exposed surfaces composed of a first material having a first bandgap energy level, and an array of second exposed surfaces that at least partially surround the first exposed surfaces, the second exposed surfaces comprising a second material composed having a second bandgap energy level. A deposition gas is deposited in the process zone. The substrate is irradiated with light that is selected to have a wavelength with a corresponding energy level that is higher than the first bandgap energy level and smaller than the second bandgap energy level. Material is selectively deposited at a higher deposition rate on the first exposed surfaces relative to the deposition of the material on the second exposed surfaces by providing an energized deposition gas in the process zone.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIGS. 1A to 10 (Prior Art) are schematic cross-sectional views of a substrate showing (i) a conformal high-k dielectric deposited on the bottom wall and spacer sidewalls prior to deposition of the metal gate therein (FIG. 1A), (ii) a seam developed during the deposition of metal into a contact plugs and metal gates when the two deposition surfaces developing from each side merge at the center (FIG. 1B), and (iii) conformal deposition of Co/Mg over the entire surface of the substrate (FIG. 1C);

FIGS. 2A and 2B (Prior Art) are transmission electron microscope photographs of a substrate showing (i) conformal high-k dielectric deposited on the spacer sidewalls of the metal gate (FIG. 2A), and (ii) a seam developed after merging of the two sidewall growing deposition surfaces in the deposition of metal into a contact plug fill process (FIG. 2B);

FIGS. 3A and 3B are schematic cross-sectional views of a partially processed substrate having first and second exposed surfaces and showing selective deposition of material onto the first exposed surfaces relative to the second exposed surfaces when exposed to the selected light and an energized deposition gas;

FIG. 4A is a flowchart of an exemplary embodiment of a process for selecting the wavelength of light for the selective deposition of material onto first exposed surfaces on a substrate relative to second exposed surfaces on the same substrate;

FIG. 4B is a flowchart of an exemplary embodiment of a process for selectively depositing material onto first exposed surfaces on a substrate relative to second exposed surfaces on the same substrate;

FIGS. 5A and 5B are schematic cross-sectional views of a substrate showing selective deposition of a metal into a contact plug feature of a substrate;

FIGS. 6A and 6B are schematic cross-sectional views of a substrate showing selective deposition of cobalt on an exposed copper surface on the substrate;

FIG. 7A shows a schematic diagram of features comprising spacers composed of silicon nitride formed on the substrate composed of silicon;

FIG. 7B is a graph showing the predicted or modeled temperatures that would occur across the surfaces of the exposed silicon substrate and within the silicon nitride spacers of the structure shown in FIG. 7A;

FIGS. 8A to 8D are graphs showing the modeled temperatures across a substrate composed of silicon and having spacers composed of silicon nitride for light having different wavelengths of 300 nm, 400 nm, 500 nm and 600 nm, and FIG. 8E is an index key for the temperatures shown in the graphs of FIG. 8A to 8D;

FIG. 9 is a schematic side sectional diagram of a substrate deposition apparatus capable of selectively depositing material on a substrate; and

FIG. 9A is a schematic sectional diagram of a gas distributor comprising a showerhead having a solid-state light source thereon.

### DESCRIPTION

A substrate 20 has an exposed surface 22 which is exposed in a process zone and which comprises a plurality of first exposed surfaces 24 and a plurality of second exposed surfaces 26 as shown in FIG. 3A. The first exposed surfaces 24 consist of at least one first material and the second exposed surfaces 26 consist of at least one second material. In one version, the first exposed surfaces 24 are spaced apart from one another to form a first array 28, and are at least partially surrounded second exposed surfaces 26 which can form a second array 30. In this exemplary embodiment, the substrate 24 comprises features 32 such as recesses 34, and include first exposed surfaces 24 which are the bottom surfaces 35 of the recesses 34, and second exposed surfaces 26 which are the sidewalls 36 of the recesses 34, or vice versa. The recesses 34 can be holes or trenches, such as contact plug holes or interconnect trenches. In another example, the recesses 34 comprise first exposed surfaces 24 which are the interior volume of a channel of a transistor with surrounding second exposed surfaces 26 which are the surfaces of sidewalls or other features surrounding the channels.

An exemplary embodiment of a substrate fabrication process capable of selectively depositing material onto the features 32 of the substrate 20 will be described with reference to the flowcharts of FIGS. 4A and 4B. The first exposed surfaces 24 of the substrate 20 are composed of, or consist of, at least one first material having a first bandgap energy level, and the second exposed surfaces 26 of the substrate are composed of, or consist of, at least one second material having a second bandgap energy level. The difference between the first and second bandgap energy levels is at least about 75×10⁻³ eV. The value of 75×10⁻³ eV is equal to the value of 3 kT at room temperature given by the Boltzmann factor.

As shown in the illustrative example of FIG. 4A, light having a particular wavelength is selected such that the energy level of the light is related to the bandgap energy level of an exposed material on the substrate 20. The selected light has a wavelength corresponding to an energy level as given by Planck's relation, λ=hc/E_{g}, where λ is the wavelength of the light, h is the Planck's constant, and E_{g} is the energy level of the light. In one example, the light is selected to have a wavelength with an energy level that is related to a first bandgap energy level of at least one first material of the first exposed surfaces 24 on the substrate 20. For example, the light can be selected to have a wavelength having an energy level that is higher than the first bandgap energy level. In addition, the light can be selected to have a wavelength and corresponding energy level that is smaller than a second bandgap energy level of at least one second material that forms the second exposed surfaces 26 on the substrate. In one example, the light is selected to have a wavelength with an energy level that is at least 5% higher than the first bandgap energy level, or even at least 10% or 30% higher. Still further, the light can also be selected to have a wavelength with an energy level that is at least 5% lower than the second bandgap energy level, or even at least 10% or 20% lower. Selective deposition of material onto the first exposed surfaces 24 relative to the second exposed surfaces 26 of a substrate 20 is achieved by exposing the substrate 20 to the selected light 27 having the desired wavelength and an energized deposition gas 29, as illustrated in FIG. 3B.

Referring to FIG. 4B, the substrate 20 is processed in a process zone of a deposition chamber having chamber walls which define and enclose the process zone as for example illustrated in FIG. 9. Before, during or after irradiating the substrate 20 with the selected light 27 as described above, an energized deposition gas 29 is provided in the process zone. The deposition gas can be introduced into the process zone and thereafter energized therein, or energized in a remote zone which is spaced apart from the process zone, and thereafter, introduced into the process zone. The deposition gas can be energized by RF energy to form a plasma or using microwave energy to activate the gas. After reacting with the substrate 20, spent deposition gas is exhausted from the process zone. The composition of the energized deposition gas 29 depends on the application. For example, the deposition gas can be composed of a dielectric deposition gas that is useful to fill the recesses 34 comprising gate metal contact plugs with a dielectric. As another example, the deposition gas can be a metal deposition gas to fill recesses 34 comprising contact plugs with a metal.

In the process zone, the entire exposed surface 22 of the substrate 20 is irradiated with the selected light 27 which is preferentially absorbed into the first exposed surfaces 24 relative to the second exposed surfaces 26. Absorption of the photons of the selected light 27 cause the first material of the first exposed surfaces 24 to rise in temperature relative to the second material of the second exposed surfaces 26. As deposition is sensitive to surface temperature, this causes the energized deposition gas 29 to generate faster deposition rates at the first exposed surfaces 24 relative to the second exposed surfaces 26. In this manner, higher deposition rates result at the light-absorbing portions of the exposed surface 22 of the substrate 20, while slower, or very little deposition, results on the light transparent portions of the exposed surface 22 of the substrate 20. For example, the deposition gas can selectively deposit material at a first deposition rate on the first exposed surfaces 24 that is at least so % higher than the second deposition rate on the second exposed surfaces 26.

During processing, the selected light 27 is provided at a sufficient intensity to selectively heat the exposed first material relative to the exposed second material, and maintain the first exposed surfaces 24 at a temperature that is at least 40° C. higher than the temperature of the second exposed surfaces 26. This difference in temperature was found to be sufficiently high to generate a higher reaction rate of the energized deposition at the first exposed surfaces 24 than the second exposed surfaces 26. A suitable light intensity is at least about 5×10⁴ W/m², or even at least about 1×10⁵ W/m², or even 4×10⁵ W/m².

It should be noted that such a selective deposition process can be further enhanced when the first exposed surfaces 24 also comprise a first material having a first thermal conductivity that is higher than a second thermal conductivity of a second material that makes up the second exposed surfaces 26. In this case, the first exposed surfaces 24 heat up even faster than the second exposed surfaces 26 when exposed to the same light intensity. It was determined when the thermal conductivity of the first material is at least about 5 times, or even at least about 10 times, the thermal conductivity of the second material, sufficiently different deposition rates are generated on each of these two materials.

To further accentuate the difference temperatures between the first and second exposed surfaces 26, the substrate can also be cooled (or even heated). For example, when the substrate 20 is cooled, heat is rapidly dissipated from the substrate 20 thereby preventing the first and second exposed surfaces 24, 26 from reaching thermal equilibrium or the same temperature over time. A suitable rate of cooling of the substrate is at least about 200° C./min or even at least about 300° C./min. The substrate 20 can be cooled by cooling a substrate support 132 which holds the substrate 20 in the process zone using a heat exchanger 144 in the support 132.

Conversely, in certain applications, heating the substrate 20 can result in a rise in temperature of the first exposed surfaces 24 relative to the second exposed surfaces 26, for example, when the first exposed surfaces 24 have a higher thermal conductivity than the second exposed surfaces, as described above. In another example, a substrate 20 comprising features 32 such as through silicon vias which eventually extend through the thickness of the substrate, when heated from below, can resultant in higher temperatures of the exposed surfaces of the through silicon vias thereby promoting higher deposition rates at these surfaces. A suitable heating method comprises heating a substrate support 132 which holds the substrate 20 in the process zone using a heat exchanger 144 in the support 132.

In an alternative embodiment, the first exposed surfaces 24 of the substrate 20 are selectively irradiated with light such that the first exposed surfaces 24 receive a higher intensity flux of light than the second exposed surfaces 26 of the substrate. In this version, the first exposed surfaces 24 are heated faster than the second exposed surfaces 26 simply because they receive a higher intensity of incident light. For example, the first exposed surfaces 24 can be selectively irradiated with a pattern of light that is generated by providing a patterned mask in front of a light source. The mask blocks portions of the light to generate a pattern which corresponds to, or is the same as, the pattern of the first exposed surfaces 24 of the substrate 20. It should be noted that the mask can also be used in conjunction with a wavelength of light selected in relation to the energy bandgap levels of the first and second materials to further maximize the temperature differential between the first and second exposed surfaces 24, 26.

### Examples

The following examples illustrate fabrication of the present process for the selective deposition of different materials on features 30 to the substrate 20. In these examples, the substrate 20 was silicon wafer having the features 32 partially formed thereon. These examples are provided to illustrate the present process and apparatus and should not be used to limit the scope of the present claims.

In the example shown in FIGS. 3A and 3B, the first material is the exposed material which forms the bottom surfaces 35 of the features 32, and the second material is the material of the sidewalls 36 of the features 32. For example, the features 32 can be gate-metal contact plugs comprising recesses 34 between the spacers which form the sidewalls 36. In this example, the bottom surfaces 35 of the recesses 34 are selectively coated with a high-k dielectric material without excessive deposition of the high-k dielectric material on the sidewalls 36 which forms the spacers. The bottom surfaces 35 of the recesses 34 comprise a first material that is silicon and which has a first bandgap energy level of 1.1. The sidewalls 36 of the spacers comprise a second material that is silicon dioxide and which has a second bandgap energy level of 8 eV. As explained above, the energy level of the light that is selected for this process needs to be higher than the first bandgap energy level and lower than the second bandgap energy level. In this example, the selected light has a wavelength of from about 200 to about 1000 nm, which corresponds to an energy level of from about 6.2 eV to 1.2 eV. In one version, light having a wavelength of 400 nm is used to irradiate the substrate 20 while an energized deposition gas comprising a plasma of Tetrakis(tert-butoxy)hafnium—Hf(OtBu)₄ gas was introduced into the process zone, to selectively deposit HfO₂ high-k dielectric material into the recesses 34. The deposition rate of the high-k dielectric was on the bottom surfaces 35 was determined to be at least 50% higher than the deposition rate of the high-k dielectric on the sidewalls 36.

In the example shown in FIGS. 5A and 5B, the first material is of the first exposed surfaces 24 which forms the bottom surfaces 35 of the recesses 34 of the features 32, and the second material is of the second exposed surfaces 26 which are the sidewalls 36 of the recesses 34. In this example, the features 32 are contact plugs which need to be filled with a metal 37 with selectively and growth of the deposited metal from the bottom surface 35 of the feature 32 to avoid formation of seams in the resultant contact plug. In this example, the bottom surfaces 35 of the recesses 34 comprise a first material that is silicon and which has a first bandgap energy level of 1.12 eV. The sidewalls 36 of the recesses 34 comprise a second material that is SiO₂ and which has a second bandgap energy level of approximately 9 eV. The energy level and corresponding wavelength of the light that is selected for this process needs to be higher than the first bandgap energy level and lower than the second bandgap energy level. In this example, the selected light has a wavelength of from about 200 nm to about 900 nm, which corresponds to an energy level of from about 6.2 eV to 1.4 eV. In one version, light having a wavelength of 400 nm is used to irradiate the substrate 20 while an energized deposition gas comprising an inductively coupled plasma of tungsten hexafluoride gas was introduced into the process zone, to selectively deposit tungsten metal material into the recesses 34. The deposition rate of the metal on the bottom surfaces 35 was determined to be at least 50% higher than the deposition rate of metal on the sidewalls 36.

In the example shown in FIGS. 6A and 6B, a first material comprising copper forms the first exposed surfaces 24 of the features 32, and the second material is the surrounding region of SiO₂ which forms the second exposed surfaces 26 of the substrate 20. In this example, the features 32 are copper interconnects 33 which need to be coated with a thin layer of cobalt (Co) 39, and optionally thereafter, a thin layer of manganese (Mn), or deposited with an alloy of cobalt and manganese (Co/Mn). In this example, copper is the first material and has a first bandgap energy level of 0 eV, and SiO₂ is the second material and has a second bandgap energy level of approximately 9 eV. The energy level and corresponding wavelength of the selected light 27 that is selected for this process needs to be higher than the first bandgap energy level of copper and lower than the second bandgap energy level of 9 eV. In this example, the selected light 27 has a wavelength of from about 200 nm to about 900 nm, which corresponds to an energy level of from about 6.2 eV to 1.4 eV. In one version, light having a wavelength of 400 nm is used to irradiate the substrate 20 while an energized deposition gas comprising an inductively coupled plasma of Bis(cyclopentadienyl)cobalt(II)—Co(C₅H₅)₂ gas was introduced into the process zone, to selectively deposit the cobalt 39 onto the copper surfaces of the copper interconnects 33 at a deposition rate that was determined to be at least 50% higher than the deposition rate of the cobalt 39 on surrounding surfaces.

The temperature profile at the first and second exposed surfaces 24, 26 of a substrate 20 when the substrate is exposed to light having a wavelength with an energy level that is higher than the first bandgap energy level of the first material of the first exposed surfaces 24 and lower than a second bandgap energy level of the material of the second exposed surfaces 26 was modeled. These modeling studies were conducted using a TOAD program on a blade server. The following modeling parameters were used: Silicon was taken as the first material which is also the substrate, Silicon nitride was taken as the second material which forms the spacer, the bandgap of silicon and silicon nitride were taken to be 1.12 eV and 5.1 eV respectively. Thermal conductivity of silicon and silicon nitride were taken to be 140 W/mK and 30 W/mK

FIG. 7A shows a schematic diagram of features 32 comprising spacers 38 composed of silicon nitride formed on the substrate 20 composed of silicon. The spacers 38 had a thickness of 8 nm and a height of 20 nm, and the distance between the spacers was 25 nm. In this example, the silicon material of the substrate 20 represented the first exposed surfaces 24 on which a high deposition rate was desirable, and the sidewalls 36 of the silicon nitride of the spacers 38 represented the second exposed surfaces 26 on which a lower deposition was desirable. In the modeling study, the substrate is exposed to a Light Emitting Diode (LED) light source which generated light having a wavelength of 400 nm which corresponds to an energy level of 3.1 eV which lies between the first bandgap energy level of the silicon of 1.1 eV and the second bandgap energy level of the silicon nitride of 5.1 eV. Still further, the thermal conductivity of silicon at 140 W/mK was at least about 5 times higher than the thermal conductivity of silicon nitride at 30 W/mK.

FIG. 7B shows the modeled temperatures that would occur within the silicon nitride spacers 38 (second exposed surfaces 26) and the surrounding exposed silicon (first exposed surfaces 24) of the substrate 20. It is seen that the heat absorbed by the silicon as represented by the darker shading is retained substantially within the silicon wafer and does not spread into the silicon nitride spacers 38. More precisely the average temperature of the first exposed surfaces 24 of silicon was about 3.9×10² K, while the average temperature of the second exposed surfaces 26 of the silicon nitride spacers was about 18% lower at 3.2×10² K. The difference in thermal conductivity between silicon nitride and silicon further retained the heat within the first exposed surfaces 24 of the silicon and prevented the temperature from rising in the nitride spacers. It was estimated that the difference in temperature between the first exposed surface 24 of the silicon at 400K (100° C.) and the middle portion of the silicon nitride spacers 38 was from about 40 to about 50° C. The temperature was expected to generate a difference in deposition rate of 50% or more between the first and second exposed surfaces 24, 26.

As another example, the temperature profile of features 32 comprising a first exposed surfaces 24 of silicon dioxide and second exposed surfaces 26 of silicon dioxide. In this example, the difference in thermal conductivity of silicon dioxide at 1 W/mK was even higher as compared to the thermal conductivity of silicon at 140 W/mK, which represented a difference in thermal conductivity of a factor of 140. Thus, even better thermal gradients are protectable for the deposition of metal on top of silicon surrounded by silicon dioxide spacers or sidewalls, as for contact plugs applications and replacement gate schemes.

The importance of selecting the correct wavelength of the light used to irradiate the first and second exposed surfaces 24, 26 of the substrate 20 are shown in FIGS. 8A to 8D. These graphs show the modeled temperature (as shown in the index key of FIG. 8E) across a substrate 20 composed of silicon and having spacers 38 composed of silicon nitride, when the substrate is exposed to light having different wavelengths of 300 nm, 400 nm, 500 nm and 600 nm. It is seen that the largest temperature difference was obtained at the lowest wavelengths of light of 300 nm, and the higher wavelengths of light reduced the temperature difference between the first and second exposed surfaces 24, 26 comprising silicon or silicon nitride respectively. According to these calculations, the optimal wavelength of light to create selectively position on a silicon surface having a first bandgap energy level of 1.12 eV relative to a silicon nitride surface having a second bandgap energy level of 5.1 eV, would be in the range of 300 to 400 nm. This proved the accuracy of the wavelength selection criteria and was predictive of the enhanced deposition rates that could be obtained using the correctly selected wavelength depending on the bandgap energy levels of the two materials on the substrate 20.

### Deposition Apparatus

An exemplary embodiment of a substrate deposition apparatus 100 capable of selectively depositing material on a substrate 20 with light exposure as described above is schematically illustrated in FIG. 9. The apparatus 100 comprises a deposition chamber 106, such as for example, a Decoupled Plasma Source (DPS™) chamber, which is an inductively coupled plasma chamber or a Sprint™ Plus tungsten deposition available from Applied Materials Inc., Santa Clara, Calif. The DPS chamber 106 can be used in the CENTURA® Integrated Processing System, commercially available from Applied Materials, Inc., Santa Clara, Calif. However, other deposition chambers may also be used in conjunction with the present invention, including, for example, capacitively coupled parallel plate chambers, magnetically enhanced chambers, and other inductively coupled deposition chambers of different designs. The chamber shown in FIG. 9 is provided only to illustrate the invention, and should not be construed or interpreted to limit the scope of the present invention.

The deposition chamber 106 comprises a housing 114 enclosing a process zone 115, and comprising one or more chamber walls 118 that include a bottom wall 122, one or more sidewalls 128, and a ceiling 130. The ceiling 130 may comprise a flat shape (as shown) or a dome shape with a multi-radius arcuate profile. The chamber walls 118 are typically fabricated from a metal, such as aluminum, or ceramic. The ceiling 130 and/or sidewalls 128 can also have a light permeable window 126 which allows light to pass into the chamber 106. A substrate transport 131 comprising a robot arm 133 is provided for transporting substrates 20 into and out of the chamber 106.

A substrate 20 with an exposed surface 22 is supported on a receiving surface 129 of a substrate support 132 in the deposition chamber 106. The substrate support 132 comprises an electrostatic chuck 134 comprising a ceramic puck 138 with an embedded electrode 140. The electrode 140 is a conductor, such as a metal, and be shaped as a monopolar or bipolar electrode. The electrostatic chuck 134 can be used to generate an electrostatic force to hold the substrate 20 placed on the receiving surface 129 of the chuck 134 by applying a DC voltage to the electrode 140, and optionally, to capacitively couple energy to a plasma formed in the chamber 106 by applying an RF voltage to the electrode 140. A plurality of heat transfer gas conduits 135 traverse the ceramic puck 24 and terminate in ports 137 on the substrate receiving surface 129 of the chuck 134 to provide heat transfer gas from a heat transfer gas supply 139 to the receiving surface 129 below the substrate 20 to heat or cool the substrate 20. The heat transfer gas, which can be for example, helium or nitrogen.

In one version, the electrostatic chuck 134 of the substrate support 132 rests on a heat exchanger 144 to heat or cool the substrate 20 placed on the receiving surface 129. In one version, the heat exchanger is a metal plate 136 which has one or more convoluted channels 146 to circulate a fluid therethrough. The fluid can be water or other suitable heat transferring medium, and is maintained at a preset temperature by a heater or cooler (not shown) and when needed pumped through the convoluted channel 146 by a fluid pump 148 to cool the metal plate 136 and the overlying electrostatic chuck 134 and substrate 20. The fluid through the convoluted channel 146 is maintained at a temperature lower or higher than the substrate temperature to raise or lower the temperature of the substrate 20 by from about 10 to about 100° C. In another version, the heat exchanger 144 comprises a thermoelectric heat pump (not shown) which may be used to heat or cool the substrate 20 depending on the polarity of the voltage applied to the heat pump.

A gas distributor 150 is provided for introducing a deposition gas into the process zone 115. In one version, the gas distributor 150 comprises a gas outlet 156 which passes through a chamber wall 118 to terminate about a periphery of the substrate 20 or may pass through the ceiling 130. In another version, the gas distributor 150 comprises a showerhead 152 with gas holes 154 therein as shown in FIG. 9A. Deposition gas is passed through the gas holes 154 to be distributed across the substrate 20. Spent deposition gas and byproducts are exhausted from the chamber 106 through an exhaust 153 which includes an exhaust port 155 that receive spent deposition gas and pass the spent gas to an exhaust conduit 157 in which there is a throttle valve 158 to control the pressure of the gas in the chamber 106. The exhaust conduit 157 is connected to and feeds one or more exhaust pumps 159. The exhaust 153 may also contain an effluent treatment system (not shown) for abating undesirable gases that are exhausted.

The deposition gas is energized in the process zone 115 or in a remote zone (not shown) to process the substrate 20 by depositing or etching material from the substrate 20. A gas energizer 160 couples energy to the deposition gas to energize the deposition gas to form one or more of dissociated gas species, non-dissociated gas species, ionic gas species, and neutral gas species. In one version, the gas energizer 160 comprises an antenna 164 comprising one or more inductor coils 168 which may have a circular symmetry about the center of the chamber 106. Typically, the inductor coils 168 comprise one or more solenoids having from about 1 to about 20 turns with a central axis coincident with the longitudinal vertical axis that extends through the deposition chamber 106. When the antenna 164 is positioned near the ceiling 130, the adjacent or abutting portion of the ceiling 130 may be made from a dielectric material, such as silicon dioxide, which is transparent to RF electromagnetic fields. The antenna 164 is powered by an antenna power supply 170 which tunes applied power with an RF match network. The antenna power supply 170 provides RF power to the antenna 164 at a frequency of typically about 50 KHz to about 60 MHz, and more typically about 13.56 MHz; and at a power level of from about 100 to about 5000 Watts.

In another version, the gas energizer 160 comprises a pair of gas energizing electrodes 174a,b that may be capacitively coupled to provide a plasma initiating energy to the deposition gas or to impart a kinetic energy to energized gas species. For example, a first electrode 174a can be the electrode 140 of the electrostatic chuck 134 and the second electrode 174b can be the ceiling 130 or chamber wall 108. The electrodes 174a,b are electrically biased relative to one another by an electrode power supply 176 that provides an RF bias voltage to the electrodes 174a,b to capacitively couple the electrodes to one another. The RF bias voltage may have frequencies of about 50 kHz to about 60 MHz, or about 13.56 MHz, and the power level of the RF bias current is typically from about 50 to about 3000 watts. The electrode power supply 176 can also provides a DC voltage to the electrodes 140 of the electrostatic chuck 134 to electrostatically hold the substrate 20.

A light source 200 is provided to irradiate with light the entire exposed surface of the substrate 20 in the process zone 115 of the chamber 106. The light source 200 can, for example, generate ultraviolet, visible or infrared light. As an example, the light source 200 generates light having a wavelength of from about 200 nm to about 1200 nm, or even from about 300 to about 1000 nm. In one version, the light source 200 provides light at a power intensity level of at least about level of at least about 5×10⁴ W/m², or even at least about 1×10⁵ W/m², or even 4×10⁵ W/m².

For example, the light source 200 can be a solid-state light source 201 which emits light in the ultraviolet, visible, or infrared spectrum. A solid-state light source 201 comprises semiconductor materials gallium nitride or aluminum gallium nitride or indium gallium nitride. Suitable light sources include an array of LEDs (light emitting diode) or laser diodes. In one version, the solid state light source comprises an LED array 204 comprising a plurality of LEDs 208, as shown in FIG. 9A, which generate light having a wavelength of from about 310 nm to about 1120 nm.

In another version, the light source 200 is a monochromatic or polychromatic lamp. The monochromatic lamp is selected to provide the desired range of wavelengths. A polychromatic lamp can also be used with a filter placed in front of the lamp to filter out undesirable wavelengths and provide light having a selective pass band of wavelengths. For example, a suitable polychromatic lamp can be used with a filter comprising a plate of transparent glass that is colored red, blue or green, which corresponds to wavelengths from about 390 nm to about 700 nm.

In one version, the light source 200 is attached to a ceiling 130 and is located in the interior of the deposition chamber 106, as shown in FIG. 9. In this version, the light source 200 provides a light exposure area which covers the exposed surface 22 of the substrate 20 as shown. The light source 200 can also be attached to the showerhead 152 of the gas distributor 150 as shown in FIG. 9A. In this example, a light source 200 comprising an LED array 204 is arranged so that each LED 208 is positioned in the space between adjacent gas holes 154 of the showerhead 152. When positioned in this manner, the LED's 208 emit light within the chamber 106 while still allowing the showerhead 152 to introduce gas into the chamber through the gas distributor holes.

It should be noted that a light source 200a can also be mounted on the exterior of the chamber 106 as shown by the dotted line structure above the window 126. In this example, the deposition chamber 106 includes a light permeable window 126 which is affixed in the ceiling 130. The light permeable window 126 is composed of a material that is substantially permeable to the light emitted by the light source 200a. For example, the light permeable window 126 can be made from transparent quartz which is permeable to light in the UV, visible and IR wavelengths. In another version, the light source 200a is mounted adjacent to a transparent window (not shown) in a chamber wall 118 to shine light through the chamber wall 118 onto the substrate 20.

The light source 200 is adapted to irradiate the entire exposed surface of the substrate 20 with light to provide selective processing of the first exposed surfaces 24 of the substrate 20 at higher processing rates while processing the second exposed surfaces 26 at lower processing rates. When the substrate 20 comprises first exposed surfaces 24 consisting of a first material having a first bandgap energy level, the light source is selected to provide light having a wavelength with an energy level that is higher than the first bandgap energy level and smaller than the second bandgap energy level of a second material of second exposed surfaces 26. In this example, a light source 200 that generates infrared light to suitable for heating, and thus increasing the processing rates of, first exposed surfaces 24 comprising a low bandgap energy level (0.67 eV) such as germanium. In contrast, a light source 200 that generates ultraviolet light is suitable for heating a high bandgap energy level (1.42 eV) material such as gallium arsenide or oxide.

The light source 200 can also be adapted to generate a pattern of light corresponding to a desired pattern of light on the exposed surface of the substrate 20 to provide selectively higher processing of those portions of the substrate 20 on which the pattern of light is incident. For example, the pattern of light can correspond to a pattern of first exposed surfaces 24 of features on the substrate 20. In one version, a light source comprising an LED array 204 with plurality of LEDs 208 is arranged so that the LEDs 208 are positioned with spaces therebetween to generate a pattern of light. As an example, when it is desirable to deposit material on the bottom surfaces 35 of recesses 34 faster than the deposition of material on the sidewalls 36 of the recesses 34, the LEDs 208 are arranged to generate a pattern of light that corresponds to the pattern of bottom surfaces 35 of the recesses 34 to provide light at first intensity light levels on the bottom surfaces 35 which is higher than a second intensity light level on the sidewalls 35 or other surrounding surfaces. Each LED light 208 generates a light beam having a beam incident area that covers just the bottom surface 35 of each recess 34 without extending beyond the edges or perimeter of the recess 34. As a result, the resultant LED array generates an array of circles of light. As another example when the substrate 20 comprises a pattern of features such as the channels of transistors which need to be selectively filled, the LEDs to regenerate of the LED array 204 are arranged to provide light in a pattern such that the first exposed surfaces 24 of the channels are irradiated with light levels having a first intensity which is higher than a second intensity of light levels irradiating surrounding surfaces.

A light source 200 can also be adapted to selectively irradiate the substrate 20 with a pattern of light. In this example, a mask (not shown) having a desired pattern of holes is placed in front of the light source 200 to create a pattern of light on the substrate 20 that corresponds to the pattern of the mask. A suitable mask can be a photo-lithography mask constructed of light opaque material with a pattern of holes corresponding to the desired pattern of light to be incident on the substrate 20. The mask is positioned directly in front of the LED array 204 to generate a pattern of light from the light passing through the holes of the mask.

The light source 200 can also be pulsed by themselves while providing a continuous supply of deposition gas into the chamber 106, and without pulsing of the deposition gas. In one application, the light source 200 is pulsed to reduce the overall intensity of the light incident on the substrate. This pulse application is useful when it is desirable to control the surface temperature of the substrate 20 to avoid overheating or reaching equilibrium temperatures across the substrate 20. Such thermal equilibrium is more likely when the thermal conductivities of the first and second materials are similar or have high values.

In another version, the gas distributor 150 is adapted to provide the deposition gas in pulses. Pulsed deposition gases are often used in atomic layer deposition. The deposition gas pulse is provided by turning on or off a gas flow control 220 such as a mass or volumetric flow meter which is coupled along a gas inlet line 222 which is fed by a gas source 224. A controller 300 controls the gas pulses according to a pulse duty cycle that is programmed into the controller 300 described below.

In one version, the light generated by the light source 200 is pulsed in synchronicity with the pulse of the deposition gas. In certain processes, such as ALD processes, the deposition gas comprises a single gas, or a plurality of gases which are provided in a pulse duty cycle. For example the deposition gas may comprise first and second gases which are provided in alternate pulses. In this example, the first deposition gas is provided during a first pulsed duty cycle, and the second deposition gas is provided in a second pulse duty cycle. The first and second pulse duty cycles do not overlap in time and the second deposition gas is provided only when the first deposition gas supply is shut off and vice versa. Each pulse duty cycle comprises a pulse on time during which the gas is provided, and a pulse off time during which the gas is shut off and is not provided to the process zone 115. In this example, the light source 200 can be pulsed in a light pulse duty cycle that synchronized with, or even the same as, a gas pulse duty cycle applied to one or all of the components of the deposition gas. This version advantageously allows the pulsed gas to be provided to the chamber 106 at the same time as when light irradiates the first exposed surfaces 24 on the substrate 20. In another version, the light pulse duty cycle is set to commence at a time which is ahead of the time of commencement of the gas pulse duty cycle to allow incident light to heat the first exposed surfaces 24 for a short time before gas is introduced into the chamber. In another application, the light source 200 is pulsed to follow the pulsing pattern of the deposition gases. For example, the light source 200 can be pulsed in the same sequence as the pulses of deposition gas.

The deposition chamber 106 can be also operated by a controller 300 comprising a computer that sends instructions via a hardware interface to operate the chamber components, including the substrate support 132 to raise and lower the substrate 20, the throttle valve 158 to control gas pressure, the gas energizer 160 to control gas energizing voltages and power levels, the light source 200 to control light intensity and wavelength, the gas flow control 220 to control on/off cycles or to pulse the deposition gas, and still other chamber components. The process conditions and parameters measured by the different detectors in the chamber 106, or sent as feedback signals by control devices such as the gas flow control 220, throttle valve 158, and other such devices, are transmitted as electrical signals to the controller 300. Although, the controller 300 is illustrated by way of an exemplary single controller device to simplify the description of present invention, it should be understood that the controller 300 may be a plurality of controller devices that may be connected to one another or a plurality of controller devices that may be connected to different components of the chamber 106; thus, the present invention should not be limited to the illustrative and exemplary embodiments described herein.

The controller 300 comprises electronic hardware including electrical circuitry comprising integrated circuits that is suitable for operating the chamber 106 and its peripheral components. Generally, the controller 300 is adapted to accept data input, run algorithms, produce useful output signals, detect data signals from the detectors and other chamber components, and to monitor or control the process conditions in the chamber 106. For example, the controller 300 may comprise a computer comprising (1) a central processing unit (CPU), such as for example a conventional microprocessor from INTEL corporation, that is coupled to a memory that includes a removable storage medium, such as for example a CD or floppy drive, a non-removable storage medium, such as for example a hard drive, ROM, and RAM; (ii) application specific integrated circuits (ASICs) that are designed and preprogrammed for particular tasks, such as retrieval of data and other information from the chamber 106, or operation of particular chamber components; and (iii) interface boards that are used in specific signal processing tasks, comprising, for example, analog and digital input and output boards, communication interface boards, and motor controller boards. The controller interface boards, may for example, process a signal from a process monitor and provide a data signal to the CPU. The computer also has support circuitry that include for example, co-processors, clock circuits, cache, power supplies and other well known components that are in communication with the CPU. The RAM can be used to store the software implementation of the present invention during process implementation. The instruction sets of code of the present invention are typically stored in storage mediums and are recalled for temporary storage in RAM when being executed by the CPU. The user interface between an operator and the controller 300 can be, for example, via a display and a data input device, such as a keyboard or light pen. To select a particular screen or function, the operator enters the selection using the data input device and can review the selection on the display.

In one version, the controller 300 comprises a computer program that is readable by the computer and may be stored in the memory, for example on the non-removable storage medium or on the removable storage medium. The computer program generally comprises process control software comprising program code to operate the chamber 106 and its components, process monitoring software to monitor the processes being performed in the chamber 106, safety systems software, and other control software. The computer program may be written in any conventional programming language, such as for example, assembly language, C++, Pascal, or Fortran. Suitable program code is entered into a single file, or multiple files, using a conventional text editor and stored or embodied in computer-usable medium of the memory. If the entered code text is in a high level language, the code is compiled, and the resultant compiler code is then linked with an object code of pre-compiled library routines. To execute the linked, compiled object code, the user invokes the object code, causing the CPU to read and execute the code to perform the tasks identified in the program.

In operation, using the data input device, for example, a user enters a process set and chamber number into the computer program in response to menus or screens on the display that are generated by a process selector. The computer program includes instruction sets to control the substrate position, gas flow, gas pressure, temperature, RF power levels, and other parameters of a particular process, as well as instructions sets to monitor the chamber process. The process sets are predetermined groups of process parameters necessary to carry out specified processes. The process parameters are process conditions, including without limitations, gas composition, gas flow rates, temperature, pressure, and gas energizer settings such as RF or microwave power levels. The chamber number reflects the identity of a particular chamber when there are a set of interconnected chambers on a platform.

A process sequencer comprises instruction sets to accept a chamber number and set of process parameters from the computer program or a process selector program and to control its operation. The process sequencer initiates execution of the process set by passing the particular process parameters to a chamber manager that controls multiple tasks in a chamber 106.

The chamber manager may include instruction sets, such as for example, substrate positioning instruction sets, gas flow control instruction sets, gas pressure control instruction sets, temperature control instruction sets, gas energizer control instruction sets, light source control instructions sets, and process monitoring instruction sets. The substrate positioning instruction sets comprise code for controlling chamber components that are used to load a substrate 20 onto the substrate support 132 or lift a substrate 20 to a desired height. For example, the substrate positioning instruction sets can include code for operating the robot arm 133 of the substrate transport 131 which transfers substrates 20 into and out of the chamber 106, for controlling lift pins (not shown) which are extended through holes in the electrostatic chuck 134, and for coordinating the movement of the robot arm 133 with the motion of the lift pins. The program code also include temperature control instruction sets to set and control temperatures maintained at different regions of the substrate 20, by for example, controlling the heat exchanger 144 and the temperature of the fluid passed therethrough and to adjust the flow of heat transfer gas passed through the heat transfer gas conduits 132. The temperature control instruction sets may also include code for controlling the temperature of walls of the chamber 106, such as the temperature of the ceiling 130.

The gas flow control instruction sets comprise code for controlling the flow rates of different constituents of the deposition gas. For example, the gas flow control instruction sets may regulate the opening size or turn on or off the gas flow control 220 to obtain the desired gas flow rates from the gas distributor 150 into the chamber 106, to pulse the flow of one or more of the gases of the deposition gas as needed. In one version, the gas flow control instruction sets comprise code to set a first volumetric flow rate of a first gas and a second volumetric flow rate of a second gas to set a desired volumetric flow ratio of the first deposition gas to the second deposition gas in the deposition gas composition. The gas pressure control instruction sets comprise program code for controlling the pressure in the chamber 106 by regulating open/close position of the throttle valve 158. The gas energizer control instruction sets comprise code for setting, for example, the RF power level applied to the electrodes 174a,b or to the antenna 164. The light source control instructions sets comprise program code for controlling the intensity of the light emitted by the light source 200, and for pulsing the light source 200 on or off as needed or in synchronicity with the pulses of the deposition gas. The process monitoring instruction sets serve as feedback control loops between the temperature monitoring instruction sets which receive temperature signals from temperature sensors, gas flow control, and other instruction sets, and adjust the power to or control the different chamber components as needed.

While described as separate instruction sets for performing a set of tasks, it should be understood that each of these instruction sets can be integrated with one another, or the tasks of one set of program code integrated with the tasks of another to perform the desired set of tasks. Thus, the controller 300 and the computer program described herein should not be limited to the specific version of the functional routines described herein; and any other set of routines or merged program code that perform equivalent sets of functions are also in the scope of the present invention. Also, while the controller is illustrated with respect to one version of the chamber 106, it may be used for any chamber described herein.

Although exemplary embodiments of the present invention are shown and described, those of ordinary skill in the art may devise other embodiments which incorporate the present invention and which are also within the scope of the present invention. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements described herein to illustrate the invention.

What is claimed is:

1. A substrate processing chamber comprising:
(a) a chamber wall enclosing a process zone having an exhaust port;
(b) a substrate support to support a substrate in the process zone;
(c) a gas distributor for providing a deposition gas to the process zone;
(d) a solid state light source capable of irradiating substantially the entire surface of the substrate with light; and
(e) a gas energizer for energizing the deposition gas.

2. A chamber according to claim 1 wherein the solid state light source is attached to a chamber wall or ceiling in the interior of the deposition chamber.

3. A chamber according to claim 1 wherein the solid state light source is attached to the gas distributor plate such that each solid state light device is positioned between adjacent gas distributor holes.

4. A chamber according to claim 1 wherein the deposition chamber comprises a ceiling composed of a material that is substantially permeable to the light and wherein the solid state light source is mounted above the ceiling.

5. A chamber according to claim 1 wherein the solid state light source comprises an LED array having a plurality of LEDs.

6. A chamber according to claim 1 wherein the substrate comprises first exposed surfaces comprising at least one first material having a first bandgap energy level, and wherein the solid state light source provides light having a wavelength with an energy level that is selected in relation to the first bandgap energy level.

7. A chamber according to claim 6 wherein the substrate further comprises a second exposed surfaces of at least one second material having a second bandgap energy level that is different from the first bandgap energy level, and wherein the solid state light source provides light having a wavelength having an energy level that is higher than the first bandgap energy level and smaller than the second bandgap energy level.

8. A chamber according to claim 7 wherein the first material has a first thermal conductivity which is higher than a second thermal conductivity of the second material.

9. A chamber according to claim 8 wherein the first material has a first thermal conductivity which is at least about 5 times the second thermal conductivity of the second material.

10. A chamber according to claim 1 wherein the substrate comprises first exposed surfaces of a first material, and the solid state light source generates a pattern of light corresponding to the pattern of first exposed surfaces on the substrate.

11. A chamber according to claim 1 wherein the solid state light source provides:
(i) light having a wavelength of from about 200 nm to about 1200 nm;
(ii) light at a power intensity level of at least about 5×10⁴ W/m².

12. A chamber according to claim 1 wherein the substrate support comprises a heat exchanger.

13. A chamber according to claim 1 wherein the gas distributor provides the deposition gas in pulses.

14. A chamber according to claim 1 wherein the solid state light source pulses the light in synchronicity with the deposition gas pulses.

15. A substrate fabrication process comprising:
(a) placing a substrate in a process zone, the substrate comprising first exposed surfaces comprising at least one first material having a first bandgap energy level;
(b) irradiating the substrate with light having a wavelength selected in relation to the first bandgap energy level of the first material; and
(c) depositing material on the first exposed surfaces by providing an energized deposition gas in the process zone.

16. A process according to claim 15 wherein the substrate comprises second exposed surfaces of at least one second material having a second bandgap energy level that is different from the first bandgap energy level, and wherein (c) comprises irradiating the substrate with light having a wavelength with an energy level that is higher than the first bandgap energy level and smaller than the second bandgap energy level.

17. A process according to claim 16 comprising providing a substrate having a first material with a first thermal conductivity which is higher than a second thermal conductivity of the second material.

18. A substrate processing method comprising:
(a) placing a substrate in a process zone, the substrate comprising an array of first exposed surfaces composed of a first material having a first bandgap energy level, and an array of second exposed surfaces that at least partially surround the first exposed surfaces, the second exposed surfaces comprising a second material composed having a second bandgap energy level;
(b) providing a deposition gas in the process zone;
(c) irradiating the substrate with light that is selected to have a wavelength with a corresponding energy level that is higher than the first bandgap energy level and smaller than the second bandgap energy level;
(d) selectively depositing material at a higher deposition rate on the first exposed surfaces relative to the deposition of the material on the second exposed surfaces by providing an energized deposition gas in the process zone; and
(e) exhausting spent deposition gas from the process zone.

19. A process according to claim 18 wherein the selected light comprises a wavelength having a corresponding energy level that is at least 5% higher than the first bandgap energy level.

20. A process according to claim 18 wherein the selected light comprises a wavelength having a corresponding energy level that is at least 5% lower than the second bandgap energy level.

21. A process according to claim 18 wherein the light selected is provided at a sufficient intensity to maintain the first exposed surfaces at a temperature that is at least 40° C. higher than the temperature of the second exposed surfaces.
